(19) United States
(12) Patent Application Publication
(10) Pub. No.: US 2006/0170076 A1
(43) Pub. Date: Aug. 3, 2006

(54) Apparatus, system, and method for reducing integrated circuit peeling

(75) Inventor: Nobuyoshi Sato, Fairview, OR (US)

Correspondence Address: LSI LOGIC CORPORATION, 1621 BARBER LANE, MS: D-106, MILPITAS, CA, 95035, US

(73) Assignee: LSI LOGIC CORPORATION, Milpitas, CA (US)

(21) Appl. No.: 11/049,065

(22) Filed: Feb. 2, 2005

(51) Int. Cl. H01L 23/58; C23F 1/00; H01L 21/461

(52) U.S. Cl. 257/632; 156/345.11; 156/345.21; 438/694; 438/745; 257/649

(57) ABSTRACT

An apparatus, system, and method are disclosed for reducing integrated circuit peeling. This invention reduces integrated circuit peeling by providing a wafer with a solventphilic layer and removing unwanted film using a solvent that is philic to the solventphilic layer. In one embodiment, a boundary is provided to reduce the rotation speed precision required to reach the desired etching distance. In certain embodiments, a wet edge etching process is used to remove unwanted film from the perimeter of the solventphilic layer. In certain embodiments, the solventphilic layer comprises a hydrophilic layer such as silicon nitride, and the solvent comprises a solution of water and hydrogen fluoride.

### BACKGROUND OF THE INVENTION

1. Field of the Invention

The invention relates generally to devices, methods, and systems for preparing integrated circuits. Specifically, the invention relates to devices, methods, and systems for reducing integrated circuit peeling by removing unwanted film.

2. Description of the Related Art

Integrated circuits are pervasive among electronic devices including computers, audio and video equipment, appliances, and industrial control equipment. The pervasive utilization of integrated circuits is largely due to their small size and ability to process data. In the foreseeable future, integrated circuits will be introduced into additional electronic devices due to their ever-increasing processing capacity, shrinking size, and decreasing price.

Integrated circuits are often fabricated on a wafer of semiconductive material whereon layers of conductive materials are placed having selective properties. As additional layers are added during preparation of the integrated circuit, unwanted film often collects around the perimeter of the wafer. Unless removed, the unwanted film may pose serious problems to the functionality of the integrated circuit and purity of the processing environment. For example, the unwanted film may later peel and be transferred to another sensitive electrical device or be scattered around, resulting in cross contamination, wherein the peeled-off fragments contaminate the processing environments of other processes.

One method for removing film is conducting a dry edge etching process. In one embodiment, the dry edge etching process includes: applying a photo mask to allow selective exposure of a wafer, dry etching to enhance the etching reaction, ashing to aid removal of the unwanted film, and cleaning with a solvent. Though dry edge etching allows for controllable etching, it is also costly and time consuming. Furthermore, dry edge etching may produce defects in the integrated circuit caused by particles left over from the photo mask step.

Another method for removing film is wet edge etching. FIG. 1 is a perspective view of one embodiment of a wet edge etching system 100. The wet edge etching system 100 may include a wafer 110, a tool 120, a spout 140, a solvent drain 190, and a vent 180. Wet edge etching may include placing the wafer 110 face down in a tool 120 configured to rotate 130 the wafer such as a Bernoulli chuck. A gaseous flow 160 is directed toward the top surface and a solvent 150 is applied to the back surface.

Due to centrifugal forces and surface tension, the solvent 150 migrates over the back surface of the wafer 110, around the wafer's edge, and on to the top surface. At a certain radial position on the top surface of the wafer 110, the surface tension of the solvent is overcome by centrifugal and gaseous flow forces, wherein the cleaning solvent 150 ceases to migrate and falls from the wafer 110. The vent 180 functions to relieve atmospheric pressure introduced to the system 100 by the gaseous flow 160, and the drain 190 functions to collect excess solution 150 as it falls from the wafer 110.

Though wet edge etching is cheaper and faster than dry edge etching, it does not allow for controlled etching, and therefore, often results in over or under etching. Over etching may destroy the functionality of the integrated circuit in that vital portions of the device may be removed along with the unwanted film. If under etching occurs, not all the unwanted film is removed and peeling remains a risk.

In short, though wet edge etching is beneficial because wet edge etching is more efficient than dry edge etching, wet edge etching is also problematic because wet edge etching is difficult to control. What is needed is a new method for removing the unwanted film from integrated circuits. More specifically, what is needed is an efficient and controllable method for removing unwanted film from integrated circuits that substantially eliminates integrated circuit peeling.

### SUMMARY OF THE INVENTION

The present invention has been developed in response to the present state of the art, and in particular, in response to the problems and needs in the art that have not yet been fully solved by currently available means and methods for reducing integrated circuit peeling. Accordingly, the present invention has been developed to provide an apparatus, system, and method for reducing integrated circuit peeling that overcome many or all of the above-discussed shortcomings in the art.

The apparatus, in one embodiment, is configured to reduce integrated circuit peeling. In one embodiment, the apparatus comprises a wafer having a top surface, a bottom surface, and an edge. The top surface is provided with a solventphilic layer and one or more integrated circuit layers. The top surface also includes a perimeter cleaned by a solvent that is philic to the solventphilic layer. In one embodiment, the solventphilic layer comprises a hydrophilic substance such as silicon nitride.

The solvent used to clean the perimeter of the wafer may comprise a solution containing water such as water and hydrogen fluoride. The apparatus substantially eliminates integrated circuit peeling due to the chemical affinity between the solvent and solventphilic layer—thus enabling the solvent to remain on the solventphilic layer longer and more effectively remove the unwanted film.

The apparatus may also include an etching boundary. In one embodiment, the etching boundary is formed by conducting a dry edge etch process on one or more integrated circuit layers. In certain embodiments, the etching boundary is at least 0.9 micrometers in height. The height of the etching boundary may improve etching controllability and efficiency by introducing a barrier to impede the migration of the solvent used in the etching process.

A system of the present invention is also presented to reduce integrated circuit peeling. The system, in one embodiment, includes a wafer having a solventphilic layer on the top surface thereof, a rotation tool configured to rotate the wafer, a solvent for removing unwanted film from the wafer, and a nozzle for applying the solvent to the wafer. In one embodiment, the rotation tool comprises a plurality of pins configured to rotate the wafer. In another embodiment, the rotation tool further comprises a spout configured to direct a gaseous flow toward a selected area of the wafer. In yet another embodiment, the system further comprises a drain for collecting the solvent used to etch the wafer.

A method is also presented for reducing integrated circuit peeling. The method in the disclosed embodiments substantially includes the steps necessary to carry out the functions presented above with respect to the operation of the described apparatus and system. In one embodiment, the method includes providing a wafer, forming a solventphilic layer on the top surface of the wafer, processing the wafer to add one or more integrated circuit layers and removing unwanted film by using a solvent that is philic to the solventphilic layer.

In certain embodiments, the method also may include forming an etching boundary by conducting a dry edge etch process on at least one integrated circuit layer. In certain embodiments, forming a solventphilic layer comprises conducting a chemical vapor deposition process to the top surface of the wafer, such that a solventphilic layer such as silicon nitride is formed. In certain embodiments, removing unwanted film comprises conducting a wet edge etch.

The disclosed method, apparatus, and system substantially eliminate integrated circuit peeling due to the chemical affinity between a selected solvent and a solventphilic layer that enables the solvent to remain on the solventphilic layer longer, and thereby more effectively remove unwanted film. These features and advantages of the present invention will become more fully apparent from the following description and appended claims, or may be learned by the practice of the invention as set forth hereinafter.

It should be noted that reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention may be practiced without one or more of the specific features or advantages of a particular embodiment. In other instances, additional features and advantages may be recognized in certain embodiments that may not be present in all embodiments of the invention.

### BRIEF DESCRIPTION OF THE DRAWINGS

In order that the advantages of the invention will be readily understood, a more particular description of the invention briefly described above will be rendered by reference to specific embodiments that are illustrated in the appended drawings. Understanding that these drawings depict only typical embodiments of the invention and are not therefore to be considered to be limiting of its scope, the invention will be described and explained with additional specificity and detail through the use of the accompanying drawings, in which:

FIG. 1 is a perspective view of a prior art wet edge etching system;

FIG. 2 is a perspective view of one embodiment of a peeling reduction system of the present invention;

FIGS. 3A-3E are perspective views of a wafer in various stags of processing in accordance with the present invention;

FIG. 4 is a process flow chart diagram of one embodiment of a method for reducing integrated circuit peeling;

FIG. 5 is a perspective view of one embodiment of the top surface of a wafer undergoing etching in accordance with the present invention; and

FIG. 6 is a line graph showing the relationship between boundary height and edge etching in accordance with the current invention.

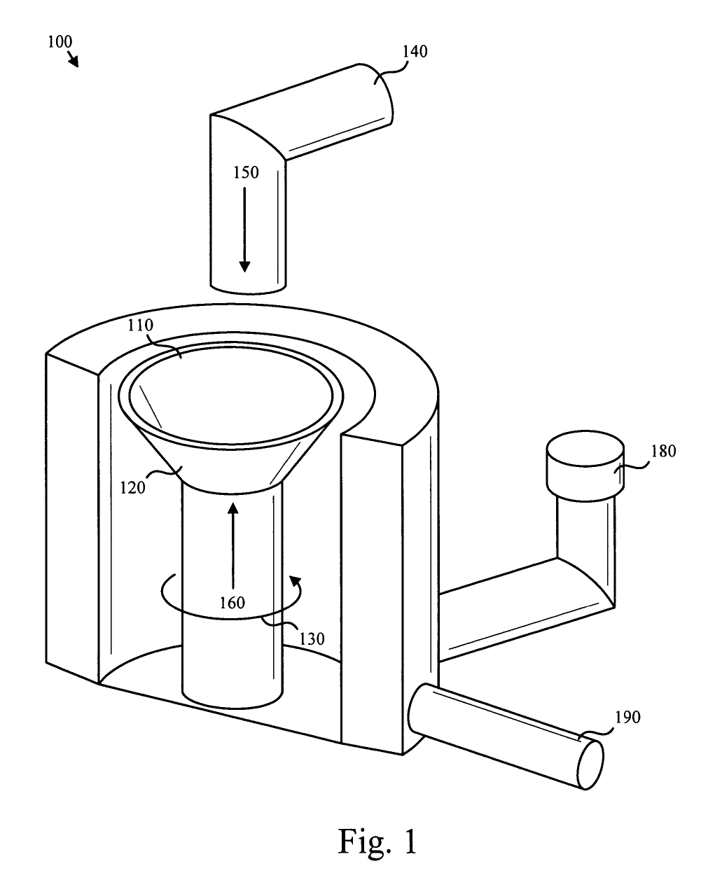

### DETAILED DESCRIPTION OF THE INVENTION

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Furthermore, the described features, structures, or characteristics of the invention may be combined in any suitable manner in one or more embodiments. In the following description, numerous specific details are provided, to provide a thorough understanding of embodiments of the invention. One skilled in the relevant art will recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams that follow are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Additionally, the order in which a particular method occurs may or may not strictly adhere to the order of the corresponding steps shown.

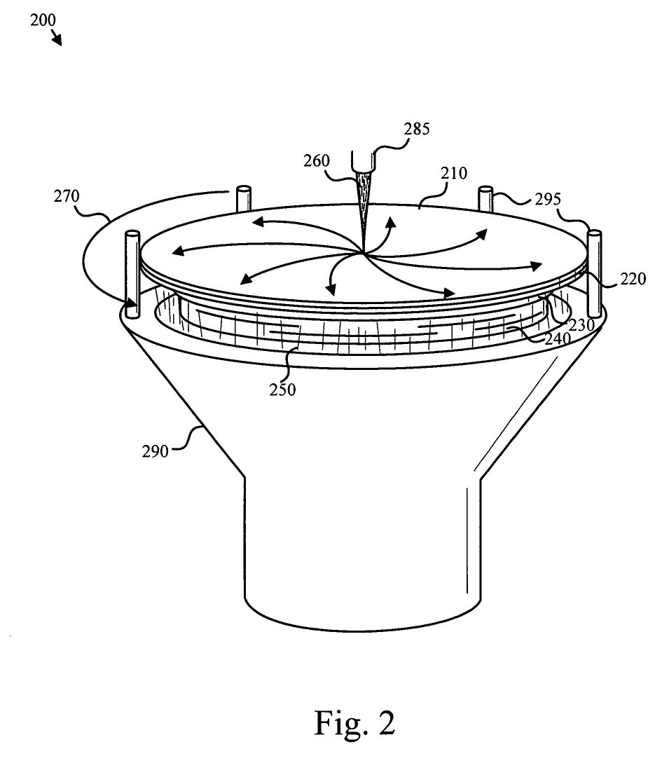

FIG. 2 is a perspective view of one embodiment of a peeling elimination system 200. As depicted, the peeling elimination system 200 includes a wafer 210, a nozzle 285, and a tool 295. The various components of the system 200 function harmoniously to efficiently and controllably remove unwanted film from the wafer 210.

The wafer 210 includes a solventphilic layer 220, at least one integrated circuit layer 230, and additional integrated circuit layers 240. The chemical composition of the solventphilic layer 220 facilitates the removal of unwanted film by allowing a cleaning solvent to remain on the solventphilic layer for a longer period of time. In certain embodiments, the at least one integrated circuit layer 230 increases etching controllability by providing a boundary to impede the migration of the cleaning solvent used in the etching process. The integrated circuit layers 230 and 240 may provide for the circuitry properties of the device.

The nozzle 285 may be configured to provide a solvent 260 that is philic to the solventphilic layer 220. The tool 295 is configured to rotate 270 the wafer 210 and may comprise a plurality of pins and a spout 290. The spout 290 may be configured to provide a gaseous flow 250 such as a stream of nitrogen gas. In certain embodiments, the system 200 comprises a Bernoulli chuck. The system 200 substantially eliminates integrated circuit peeling due to the chemical affinity between the solvent 260 and solventphilic layer 220 thereby enabling the etching solvent 260 to remain on the solventphilic layer 220 resulting in more effective removal of unwanted film.

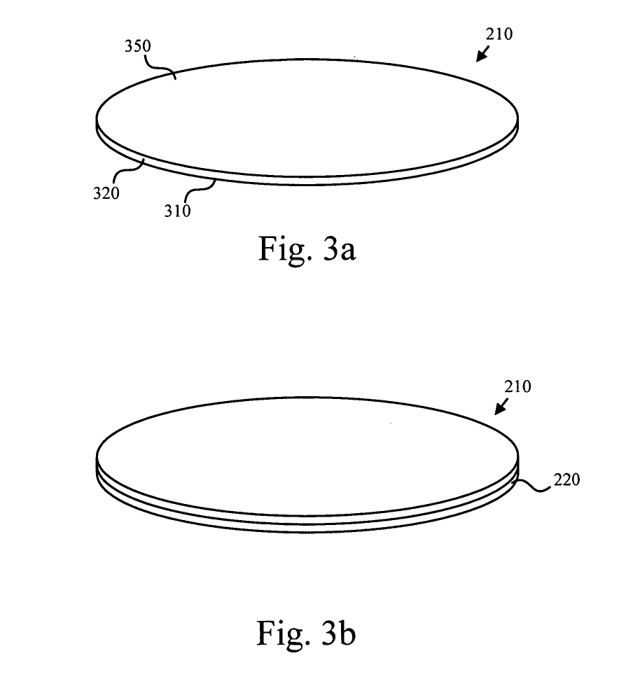

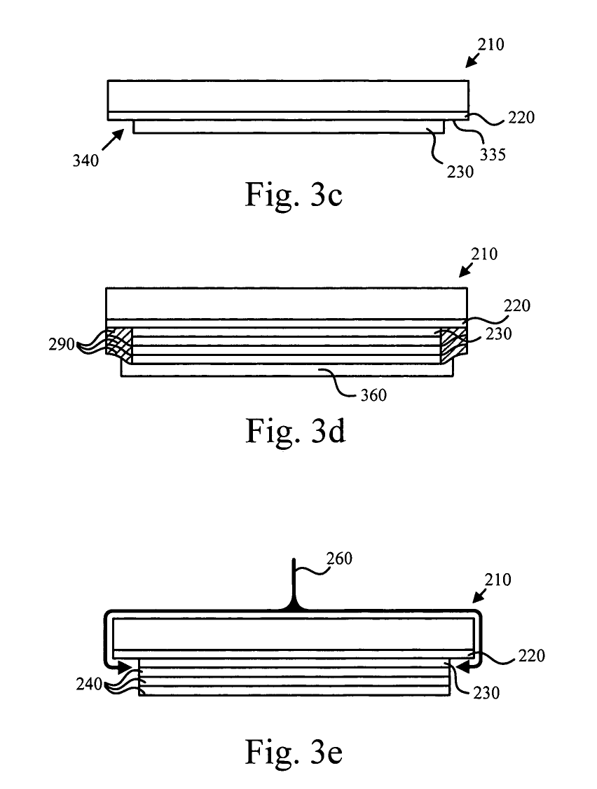

FIGS. 3A-3E illustrate a wafer 210 during different stages of processing. Through the depicted stages of processing, the wafer 210 comprises a solventphilic layer 220 and perimeter 335, one or more integrated circuit layers 230, a boundary 340, unwanted film 360, and additional integrated circuit layers 240. Though the boundary 340 is presented in the depicted embodiment, it is not a necessary component of all embodiments.

In one embodiment, the wafer 210 comprises a thin slice of polished, circular silicon. The top surface 310 corresponds to at least one circuit layer 230. Furthermore, the top surface 310 may be positioned downward during much of the described process to facilitate the formation of the solventphilic layer 220, boundary 340, and additional integrated circuit layers 240.

The chemical composition of the solvenphilic layer 220 is philic to the composition of the solvent 260 used to remove unwanted film. For example, in embodiments where the solvent 260 contains water, the solventphilic layer 220 may comprise a hydrophilic layer such as silicon nitride. The chemical affinity between the solvent 260 and solventphilic layer 220 enables the solvent 260 to remain on perimeter 335 of the solventphilic layer 220 longer, whereby the solvent 260 can more effectively remove unwanted film that causes peeling. In one embodiment, the solventphilic layer 220 may be created via low-pressure chemical vapor deposition.

In certain embodiments, the edge of the one or more integrated circuit layers 230 provides a boundary 340. In certain embodiments, the boundary 340 is at least 0.9 micrometers in height in order to effectively impede inward flow of the solvent 260. The height of the etching boundary 340 may facilitate etching controllability and efficiency by introducing a burrier that impedes the migration of the solvent 260 used in the etching process.

In certain embodiments, the unwanted film 360 comprises a residue left on the perimeter 335 of the solventphilic layer 220 by the addition of the integrated circuit layers 240. Unless removed, the unwanted film 360 may later peel and be transferred to another sensitive electrical device or be scattered around, resulting in contamination of the processing environments. The composition of the solvent 260 facilitates removal of the unwanted film because the solvent is philic to the composition of the solventphilic layer 220. For example, in an embodiment wherein the solventphilic layer 220 is silicon nitride, the solvent 260 may comprise water and hydrogen fluoride.

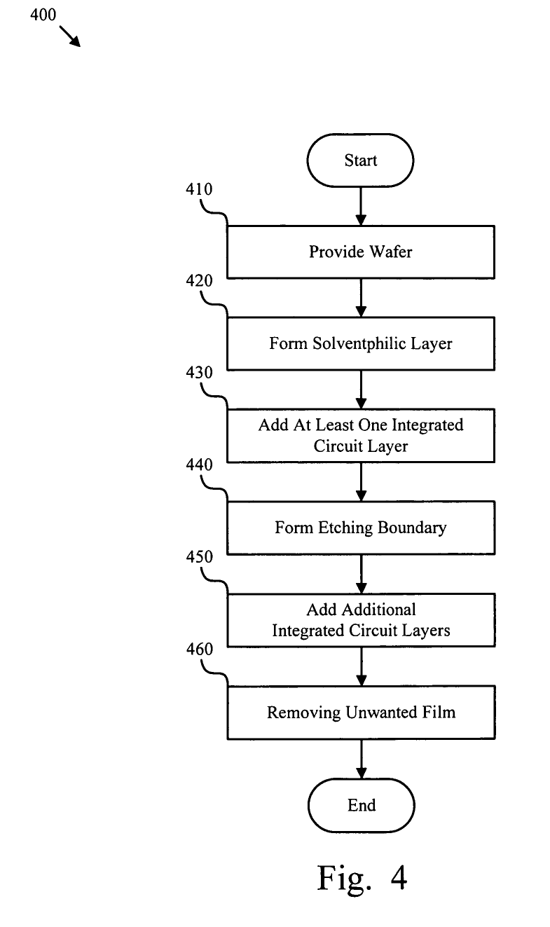

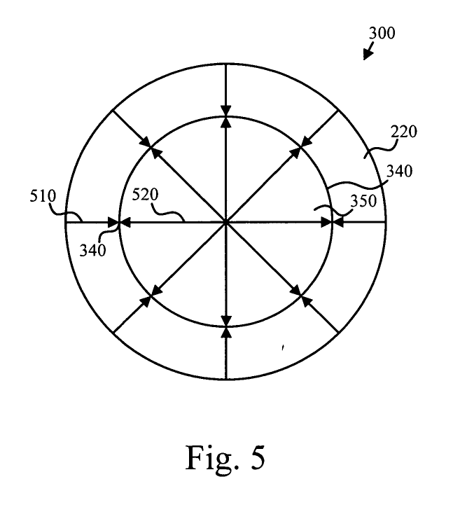

FIG. 4 is a process flow chart diagram of one embodiment of a method 400 for reducing integrated circuit peeling. The depicted method 400 includes providing 410 a wafer, forming 420 a solventphilic layer, adding 430 at least one integrated circuit layer, forming 440 a boundary, adding 450 additional integrated circuit layers, and removing 460 unwanted film 360. In certain embodiments, the method 400 is conducted without forming 440 a boundary.

Providing 410 a wafer may include providing an integrated circuit wafer 210, such as the integrated circuit wafer 210 depicted in FIG. 2. Forming 420 a solventphilic layer may include conducting a low-pressure chemical vapor deposition process. In certain embodiments, the chemical used in the chemical vapor deposition is nitrogen, such that a layer of silicon nitride forms on the top surface 310 of the wafer 210. Formation of the solventphilic layer 220 facilitates more complete removal of unwanted film 360 from the wafer 210, thereby reducing the risk of peeling.

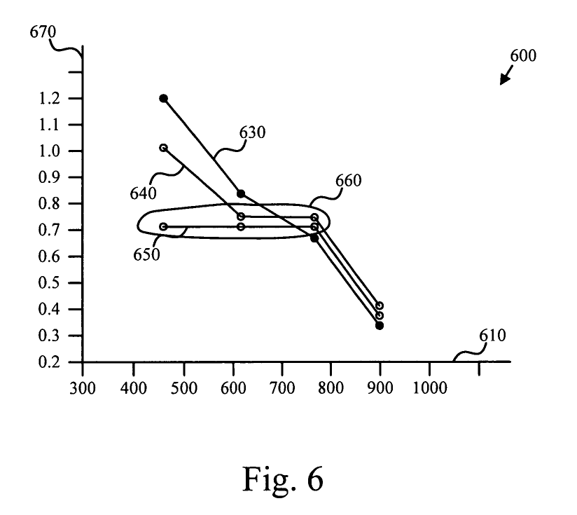

Adding 430 at least one integrated circuit layer includes adding an integrated circuit layer 230 above the solventphilic layer 220. In certain embodiments, the integrated circuit layer 230 not only contributes to the conductive circuitry of the wafer 210, but also functions as a boundary 340 during the removal of unwanted film 360. As further illustrated in FIG. 6, in certain embodiments, the etching boundary 340 is at least 0.9 micrometers in height.

Forming 440 a boundary may include etching at least one integrated circuit layer 230. In certain embodiments, the boundary 340 is formed using dry edge etching. Using dry edge etching on the at least one integrated circuit layer 230 allows for precise control of the etching boundary 340. Once the at least one integrated circuit layer 230 is etched, the side of the at least one integrated circuit layer 230 functions as a boundary 340 for subsequent etching processes.

Adding 450 additional integrated circuit layers may include adding subsequent integrated circuit layers 230 of varying conductive properties on top of the at least one integrated circuit layer 230. The process of adding additional layers 240 may produce an unwanted film 360 on the perimeter 335 of the solventphilic layer 220. Unless removed, the unwanted film 360 may later peel and be transferred to another sensitive electrical device or be scattered around, resulting in cross contamination of the processing environments of other processes.

Removing 460 unwanted film 360 may include etching the wafer 210. In one embodiment, the unwanted film 360 is removed by performing a wet edge etch. In one embodiment, the integrated circuit 380 is first positioned with the top surface 310 down. Subsequently, the wafer 210 is rotated as the solvent 260 is added to the bottom surface 330 of the wafer 210.

The centrifugal force of the rotating device 280 forces the solvent 260 to migrate across the bottom surface 330 of the device 280 and over the device's edge 320. The surface tension of the solvent 260 allows the solvent 260 to continue migrating onto the solventphilic layer 220 and toward the etching boundary 340. Due to the philic relationship between the solvent 260 and the solventphilic layer 220, the solvent 260 has a greater propensity to remain on the solventphilic layer 220 and remove the unwanted film 360. Thus, the compositional relationship between the solvent 260 solventphilic layer 220 facilitates efficient and controlled removal of unwanted film 360.

FIG. 5 is a perspective view of one embodiment of the top surface 310 of a wafer 210 undergoing etching. The wafer 210 includes a solventphilic layer 220, a boundary 340, and at least one integrated circuit layers 240. The various components of the device function harmoniously to ensure the proper migration distance of the solvent 260 over the wafer 210.

As the solvent 260 migrates over the solventphilic layer 220 the centrifugal and airflow forces 520 oppose the inward migration 510 of the solvent 260 resulting from solvent's 260 surface tension. At a certain radial position 530 the centrifugal and airflow forces 520 match the surface tension forces 510, and the solvent 260 will not progress any further. As more solvent 260 accumulates, gravitational forces cause the solvent 260 to drip from the top surface 310 of the wafer 210 and spray outward due to centrifugal forces 520. As illustrated in FIG. 6, in embodiments using a boundary of at least 0.9 micrometers, the etching distance is relatively insensitive to the rotation speed of the wafer 210.

FIG. 6 is a line graph 600 showing the relationship between etching boundary height 630, 640, and 650, edge etching distance 620, and integrated circuit rotation speed 610. In short, reaching a target etching distance 620 becomes less dependant upon rotation speed 610 as the etching boundary increases in height. The graph 600 depicts results for a target etching distance 620 of 0.7 millimeters.

In an embodiment where the etching boundary height is 0 micrometers, the etching distance 620 is substantially dependant upon the rotation speed 610 of the integrated circuit. In an embodiment where the etching boundary height is 0.5, the etching distance is substantially dependant upon the rotation speed 610 of the integrated circuit with the exception of the rotation speeds between 600-750 revolutions per minute. However, in an embodiment with a boundary of 1.0 micrometers, the etching distance is less dependant upon rotation speed in as much as the target etching distance of 0.7 millimeters can be met anywhere from 450-750 revolutions per minute. Thus, with a higher etching boundary 340, the etching distance is less sensitive to the rotation speed 610.

The present invention substantially reduces peeling in a wafer processing environment. The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method for reducing integrated circuit peeling, the method comprising:
providing a wafer having a top surface, a bottom surface, and an edge, the top surface corresponding to at least one integrated circuit layer;
forming a solventphilic layer on the top surface of the wafer;
processing the wafer to add at least one integrated circuit layer; and
removing unwanted film by using a solvent that is philic to the solventphilic layer.

2. The method of claim 1, further comprising forming a boundary by conducting a dry edge etch process on the at least one integrated circuit layer.

3. The method of claim 2, wherein the etching boundary is at least 0.9 micrometers in height.

4. The method of claim 1, wherein forming a solventphilic layer comprises conducting a chemical vapor deposition process.

5. The method of claim 1, wherein forming a solventphilic layer comprises coating the wafer.

6. The method of claim 1, wherein removing unwanted film comprises conducting a wet edge etch.

7. The method of claim 1, wherein the solvent comprises water and hydrogen fluoride.

8. The method of claim 1, wherein the solventphilic layer comprises a hydrophilic material.

9. The method of claim 1, wherein the solventphilic layer comprises silicon nitride.

10. An apparatus for reducing integrated circuit peeling, the apparatus comprising:
a wafer having a top surface, a bottom surface, and an edge, the top surface corresponding to at least one integrated circuit layer;
a solventphilic layer formed on the top surface of the wafer;
at least one integrated circuit layer adjacent to the solventphilic layer; and
a perimeter cleaned by a solvent that is philic to the solventphilic layer.

11. The apparatus of claim 10, further comprising a boundary formed by conducting a dry edge etch process on the at least one integrated circuit layer.

12. The apparatus of claim 11, wherein the etching boundary is at least 0.9 micrometers in height.

13. The apparatus of claim 10, wherein the solventphilic layer is formed via a chemical vapor deposition.

14. The apparatus of claim 10, wherein the solvent comprises water and hydrogen fluoride.

15. The apparatus of claim 10, wherein the solventphilic layer comprises a hydrophilic material.

16. The apparatus of claim 10, wherein the solventphilic layer comprises silicon nitride.

17. A system for reducing integrated circuit peeling, the system comprising:
a wafer having a solventphilic layer on the top surface thereof;
a tool configured to rotate the wafer;
a solvent for removing unwanted film from the wafer; and
a nozzle for applying the solvent to the wafer.

18. The system of claim 17, wherein the tool comprises a plurality of pins configured to rotate the wafer.

19. The system of claim 17, wherein the tool comprises a Bernoulli chuck.
